(19) United States
(12) Patent Application Publication
(10) Pub. No.: US 2016/0083648 A1
(43) Pub. Date: Mar. 24, 2016

(54) PHOSPHOR, METHOD FOR PRODUCING THE SAME, AND LIGHT-EMITTING DEVICE USING THE SAME

(71) Applicant: Kabushiki Kaisha Toshiba, Minato-ku (JP)

(72) Inventors: Yumi FUKUDA, Setagaya (JP); Masahiro KATO, Naka (JP)

(73) Assignee: Kabushiki Kaisha Toshiba, Minato-ku (JP)

(21) Appl. No.: 14/845,838

(22) Filed: Sep. 4, 2015

(30) Foreign Application Priority Data
Sep. 22, 2014 (JP) 2014-192156

(51) Int. Cl. C09K 11/77; H01L 33/50

(52) U.S. Cl. CPC C09K 11/7721; H01L 33/504

(57) ABSTRACT

A present embodiment is to provide a phosphor that has favorable temperature characteristics, that can emit yellow light having excellent color rendering properties, and that has high quantum efficiency. The phosphor exhibits a luminescence peak in a wavelength range of 500 to 600 nm when excited with light having a luminescence peak within a wavelength range of 250 to 500 nm. The phosphor is represented by the following formula (1): ((M₁₋ₓCe)ₓ)_{2y}Al_{z}Si_{10-z}OᵤN_{w} (1) (wherein M includes at least one of Ba, Sr, Ca, Mg, Li, Na, and K, and 0<x≦1, 0.8≦y≦1.1, 2≦z≦3.5, u≦1, 1.8≦z−u, and 13≦u+w≦15 are satisfied). The phosphor has a paramagnetic defect density of 5×10¹⁵ per gram or less.

### CROSS-REFERENCE TO RELATED APPLICATIONS

This application is based upon and claims the benefit of priority from the prior Japanese Patent Application No. 2014-192156, filed on Sep. 22, 2014, the entire contents of which are incorporated herein by reference.

### BACKGROUND

1. Field of the Invention

An embodiment of the present invention relates to a phosphor, a light-emitting device, and a method for producing the phosphor.

2. Description of the Related Art

A white light-emitting device comprises a combination of, for example, a phosphor that emits red light by excitation with blue light, a phosphor that emits green light by excitation with blue light, and a blue LED. In contrast, use of a phosphor that emits yellow light by excitation with blue light enables a white light-emitting device to be formed with fewer kinds of phosphors. As such a phosphor that emits yellow light by excitation with blue light, for example, a Eu-activated orthosilicate phosphor is known.

Various applications of such yellow phosphors have been examined, and demands for, e.g., temperature characteristics, quantum efficiency, and color rendering properties in yellow light-emitting phosphors have been increased.

### BRIEF DESCRIPTION OF THE DRAWINGS

FIGS. 1A to 1C are views illustrating the crystal structure of Sr₂Al₃Si₇ON₁₃;

FIG. 2 is a schematic view illustrating the configuration of a light-emitting device according to an embodiment;

FIG. 3 is a schematic view illustrating the configuration of a light-emitting device according to another embodiment;

FIG. 4 shows the emission spectra of the phosphors of Examples and Comparative Example;

FIG. 5 shows the XRD profile of the phosphor of Example 1;

FIG. 6 shows the XRD profile of the phosphor of Example 2;

FIG. 7 shows the XRD profile of the phosphor of Comparative Example; and

FIG. 8 is a view showing a relationship between a paramagnetic defect density and a luminous efficiency in each phosphor.

### DETAILED DESCRIPTION

A phosphor according to an embodiment of the present embodiment exhibits a luminescence peak in a wavelength range of 500 to 600 nm when excited with light having a luminescence peak within a wavelength range of 250 to 500 nm,

wherein said phosphor is represented by the following formula (1):

((SrₚM₁₋ₚ)₁₋ₓCeₓ)_{2y}Al_{z}Si_{10-z}OᵤN_{w} (1)

wherein M is at least one of alkaline earth metals; and

0≦p≦1,

0<x≦1,

0.8≦y≦1.1,

2≦z≦3.5,

0<u≦1,

1.8≦z−u, and

13≦u+w≦15

are satisfied; and

said phosphor having paramagnetic defects and a paramagnetic defect density of said phosphor being 5×10¹⁴ per gram or less.

Embodiments will now be explained with reference to the accompanying drawings.

A phosphor according to an embodiment exhibits a luminescence peak in a wavelength range of 500 to 600 nm when excited with light having a luminescence peak within a wavelength range of 250 to 500 nm, and is therefore a phosphor that can emit light in the region from yellow-green to orange. The phosphor mainly emits light in the yellow region. Therefore, hereinafter, the phosphor according to the present embodiment may be referred to as a yellow light-emitting phosphor.

Such a phosphor comprises a host crystal having a crystal structure that is substantially identical to the crystal structure of Sr₂Al₃Si₇ON₁₃, and the host crystal is activated with a luminescence center element such as Ce. The composition of the yellow light-emitting phosphor according to the present embodiment is represented by the following formula (1):

((SrₚM₁₋ₚ)₁₋ₓCeₓ)_{2y}Al_{z}Si_{10-z}OᵤN_{w} (1)

wherein M is at least one of alkaline earth metals; and

0≦p≦1, preferably 0.85≦p<1,

0<x≦1, preferably 0.001≦x≦0.5,

0.8≦y≦1.1, preferably 0.85≦y≦1.06,

2≦z≦3.5, preferably 2.5≦z≦3.3,

0<u≦1, preferably 0.001≦u≦0.8,

1.8≦z−u, preferably 2.0≦z−u, and

13≦u+w≦15, preferably 13.2≦u+w≦14.2

are satisfied.

As shown in the formula (1) described above, some of metal elements forming a host crystal are substituted by a luminescence center element Ce. M is at least one of the alkaline earth metals, and is preferably at least one selected from Ba, Ca, and Mg. There may be a case in which p of 1 is desirable for optimizing the luminescence properties of the phosphor. However, even in such a case, there is a case in which metals other than Sr and Ce are contained as unavoidable impurities. In general, in such a case, the effects of the present embodiment are sufficiently exhibited.

A case in which Ce is 0.1 mol % or more of the total of Sr, M, and Ce can result in sufficient luminous efficiency. It is unnecessary to contain Sr and M (x=1); however, when x is less than 0.5, reduction in luminous efficiency (concentration quenching) can be suppressed as much as possible. Accordingly, x is preferably 0.001 or more and 0.5 or less. The containing of the luminescence center element Ce allows the phosphor according to the present embodiment to emit light in the yellow region, i.e., to emit light having a peak in a wavelength range of 500 to 600 nm when excited with light having a peak in a wavelength range of 250 to 450 nm. Desired properties are not impaired even when some of Ce is substituted by another metal element like unavoidable impurities. Examples of such unavoidable impurities include Tb, Eu, Mn, and the like. Specifically, the percentage of the unavoidable impurities to the total of Ce and the unavoidable impurities is preferably 15 mol % or less, more preferably 10 mol % or less.

In order to reduce crystal defects to prevent efficiency from decreasing, y is allowed to be 0.8 or more, preferably 0.85 or more. In contrast, for preventing luminous efficiency from decreasing due to the precipitation of an excessive alkaline earth metal as a heterogenous phase, y of 1.1 or less is needed, and it is preferable that y is 1.06 or less. Accordingly, 0.8≦y≦1.1 is needed, and 0.85≦y≦1.06 is preferable.

For preventing luminescence properties from deteriorating due to the precipitation of excessive Si as a heterogenous phase, z of 2 or more is needed, and z of 2.5 or more is preferable. In contrast, for preventing luminescence properties from deteriorating due to the precipitation of excessive Al as a heterogenous phase in z of more than 3.5, z of 3.5 or less is needed, and z of 3.3 or less is preferable. Accordingly, 2≦z≦3.5 is needed, and 2.5≦z≦3.3 is preferable.

For inhibiting luminous efficiency from deteriorating due to increase in crystal defects, u of 1 or less is needed, and u of 0.8 or less is preferable. In contrast, in order to maintain a desired crystal structure and to appropriately maintain the wavelength of an emission spectrum, u is preferably allowed to be 0.001 or more. Accordingly, u≦1 is needed, and 0.001≦u≦0.8 is preferable.

In order to maintain a desired crystal structure in the phosphor according to the embodiment and to inhibiting a heterogenous phase from being generated when the phosphor is produced, a value of z−u of 1.8 or more is needed, and a value of z−u of 2.0 or more is preferable. For the same reason, 13≦u+w≦15 is needed, and 13.2≦u+w≦14.2 is preferable.

The phosphor according to the present embodiment includes all of the preferred conditions mentioned above and is therefore capable of emitting yellow light excellent in color rendering properties with a high degree of efficiency when excited with light having a luminescence peak in a wavelength range of 250 to 500 nm. Moreover, the yellow light-emitting phosphor according to the present embodiment has features of high efficiency, a wide light-emitting half-width, and favorable temperature characteristics due to a few defects contained in a crystal as mentioned below.

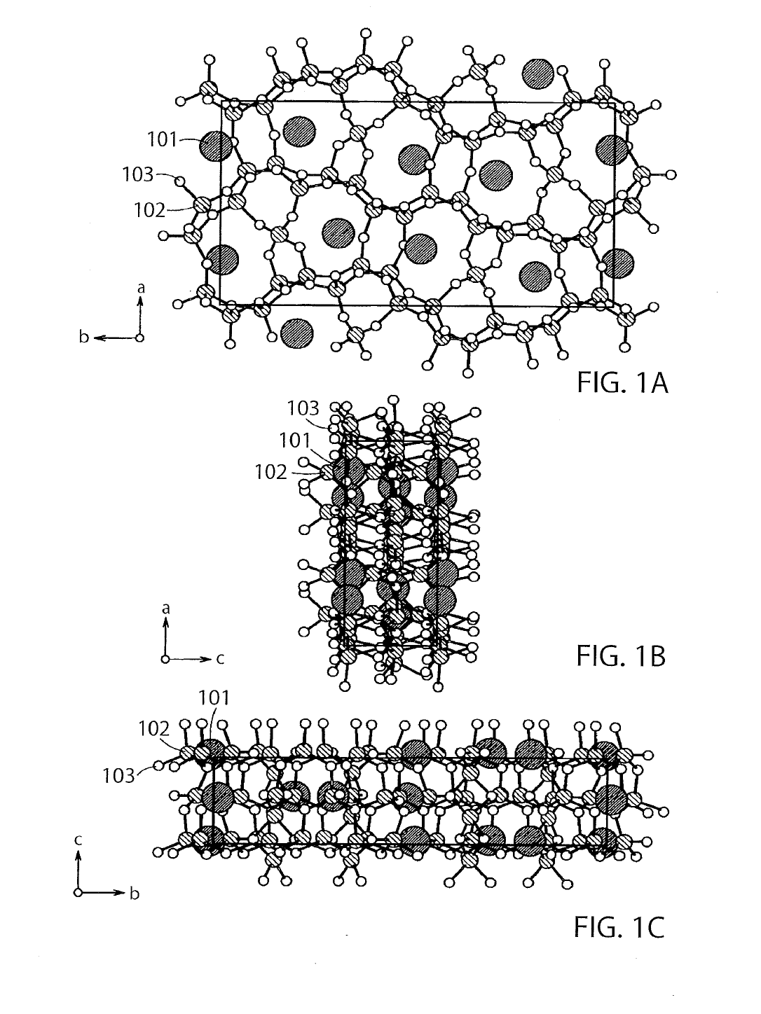

The yellow light-emitting phosphor according to the embodiment of the present invention is based on an inorganic compound having a crystal structure that is substantially identical to the crystal structure of Sr₂Al₃Si₇ON₁₃, in which some of elements Sr forming the compound are substituted by luminescence center ions Ce. The crystal structure of Sr₂Al₃Si₇ON₁₃ is as illustrated in FIG. 1. In FIG. 1, an atom 101 is a Sr atom or a Ce atom, an atom 102 is a Si atom or an Al atom, and an atom 103 is an O atom or a N atom. It may be considered that the phosphor is based on Sr₂Al₃Si₇ON₁₃, in which Si and Al are replaced with each other, or O and N are replaced with each other, and another metal element such as Ce forms a solid solution. In the present embodiment, such a crystal is referred to as a Sr₃Al₃Si₁₃O₂N₂₁-based crystal. Such replacement or the like may result in slight change of a crystal structure but rarely results in change of an atom position to such a large extent that a chemical bond between skeleton atoms is cleaved. The atom position is determined by the crystal structure, the site occupied by the atom, and its coordinate. The Sr₂Al₃Si₇ON₁₃ crystal belongs to a monoclinic system, particularly to an orthorhombic system, with lattice constants of a=11.8 Å, b=21.6 Å, and c=5.01 Å. The crystal belongs to the space group Pna21.

The phosphor according to the embodiment of the present invention is based on an inorganic compound having a crystal structure that is substantially identical to the crystal structure of Sr₂Al₃Si₇ON₁₃, in which some of elements M forming the compound are substituted by luminescence center ions Ce, and the composition of each element is specified into a predetermined limit. In this case, preferred properties of high efficiency, a wide light-emitting half-width, and excellent temperature characteristics are exhibited.

The yellow light-emitting phosphor according to the embodiment of the present invention has a feature that a paramagnetic defect density determined by a signal having a g value of around 2.0, detected by an electron spin resonance (ESR) method, is low. Specifically, the phosphor according to the embodiment preferably has a paramagnetic defect density of 5×10¹⁴ per gram or less.

Such a paramagnetic defect density can be measured from an ESR signal. Specifically, the ESR measurement is performed by sweeping a magnetic field while irradiating a sample with microwaves. ESR is spectral analysis in which the transition between levels, occurring when unpaired electrons are present in a magnetic field, is observed. Therefore, in ESR, absorption is observed when the energy spacing between the levels, increased with increasing the magnetic field, and microwave energy are equal to each other. An ESR spectrum is usually obtained from a differential curve, an absorption curve is obtained by once integrating the differential curve, and a signal strength is obtained by twice integrating the differential curve. The paramagnetic defect density can be determined from the area obtained by the integration performed twice.

The yellow light-emitting phosphor according to the present embodiment can be produced by an arbitrary method. Specifically, the phosphor according to the embodiment of the present invention can be produced by mixing raw material powders containing each element and by repeatedly firing and crushing the mixture. In this case, it is preferable to use specific raw materials and to control firing atmosphere.

A Sr-containing raw material can be selected from nitrides, silicides, carbides, carbonates, hydroxides, and oxides of Sr. A M-containing raw material can be selected from nitrides, silicides, carbides, carbonates, hydroxides, and oxides of M. An Al-containing raw material can be selected from nitrides, oxides, and carbides of Al, and a Si-containing raw material can be selected from nitrides, oxides, and carbides of Si. A Ce-containing raw material can be selected from chlorides, oxides, nitrides, and carbonates of Ce.

Nitrogen can be given from a nitride raw material or from atmosphere containing nitrogen by firing in the atmosphere, and oxygen can be given from an oxide raw material or from a surface oxidation coating of a nitride raw material.

For example, Sr₃N₂, AlN, Si₃N₄, Al₂O₃ and AlN, and CeCl₃ are mixed in preparation composition which may form composition of interest (raw material mixing step). Sr₂N, SrN, or the like, or a mixture thereof may be used instead of Sr₃N₂. For obtaining a uniform mixed powder, it is desirable to perform dry mixing of the raw material powders in order of increasing mass.

The raw materials can be mixed, for example, using a mortar in a glove box. The mixed powders are encased in a crucible and fired under predetermined conditions, to thereby obtain the phosphor according to the present embodiment. The material of the crucible is not particularly limited but can be selected from boron nitride, silicon nitride, silicon carbide, carbon, aluminum nitride, sialon, aluminum oxide, molybdenum, tungsten, and the like.

It is desirable to fire the mixed powders (firing step) at a pressure that is not less than atmospheric pressure. The firing at the pressure that is not less than atmospheric pressure is advantageous in view of inhibiting silicon nitride from decomposing. For suppressing the decomposition of silicon nitride at high temperature, a pressure (absolute pressure) of 5 atmospheres or more is more preferred, and a firing temperature ranging from 1500 to 2000° C. is preferable. Such conditions allow a sintered body of interest to be obtained without causing trouble such as sublimation of a material or a product. In the present embodiment, a plurality of firing steps are repeatedly performed as mentioned below, and it is preferable to perform some or all of the firing steps under a pressurization condition. A firing temperature of 1800 to 2000° C. is more preferred.

The firing atmosphere preferably has a low oxygen content in every firing step. This is because oxidation of raw materials such as AlN is avoided. Specifically, firing in nitrogen atmosphere, high-pressure nitrogen atmosphere, or deoxidation atmosphere is desired. The atmosphere may contain up to around 50 vol % of hydrogen molecules.

In the present embodiment, it is preferable to perform firing at the above-described temperature for 0.5 to 20 hours, to then take a fired product out of the crucible to crush the fired product (crushing step), and to re-fire the crushed product under the same conditions. A series of such steps of taking-out, crushing, and firing is repeated around 0 to 10 times. In at least one of the crushing steps, crushing is thoroughly performed so that a phosphor is made into smaller particles than those in the other crushing steps. A crushing step for forming smaller phosphor particles as described above is particularly referred to as a grinding step. It is preferable to perform the grinding step just before the last firing. The grinding step can also be performed just after the crushing step.

It is preferable to thoroughly perform the grinding. Specifically, it is preferable to perform preliminary crushing using a grinding machine such as a rotary crusher, a hammer mill, or a wing mill as needed and to then perform crushing with a mortar, a planetary mill, and a ball mill until a particle diameter (central particle diameter D50) becomes 10 μm or less. Grinding conditions can be adjusted by changing grinding time, the diameter of a ball for use in the grinding, the material of the ball, the number of times of the grinding, and the like.

As described above, the grinding may result in the application of stress to the product and therefore in increase in paramagnetic defects. However, firing under such specific firing conditions as described above results in decrease in paramagnetic defects immediately after the grinding and finally in less paramagnetic defects than those in a case in which any grinding step is not inserted. This is considered to be because, although paramagnetic defects (that are considered to be nitrogen defects or oxygen defects) are present on the surface of a crystal and in the crystal, only the defects present on the surface are mainly restored by the firing. In other words, this is considered to be because the grinding results in reduction in primary particle diameter and in increase in specific surface area, and therefore, the number of the surface paramagnetic defects restored by the subsequent firing is more than that in the case in which any grinding step is not inserted.

Crushing except the grinding step, particularly the crushing performed after the last firing, is preferably performed using a mortar. This is because increase in paramagnetic defects due to the crushing is suppressed as mentioned above.

Such a firing method and a crushing method result in advantages that the fusion of crystal grains hardly occurs and that it is easy to generate a powder with a uniform composition and crystal structure.

After the firing, as needed, post-treatment such as cleaning is performed to obtain a phosphor according to an embodiment. For example, pure water, an acid, or the like can be used in the cleaning. Examples of the acid that can be used include inorganic acids such as sulfuric acid, nitric acid, hydrochloric acid, and hydrofluoric acid; organic acids such as formic acid, acetic acid, and oxalic acid; mixed acids thereof; and the like.

Before or after acid cleaning, post-annealing treatment may be performed as needed. The order of the post-annealing and the acid cleaning can be appropriately changed depending on an objective. The post-annealing treatment can be performed, for example, in reducing atmosphere containing nitrogen and hydrogen. Crystallinity and luminous efficiency are improved by such post-annealing treatment.

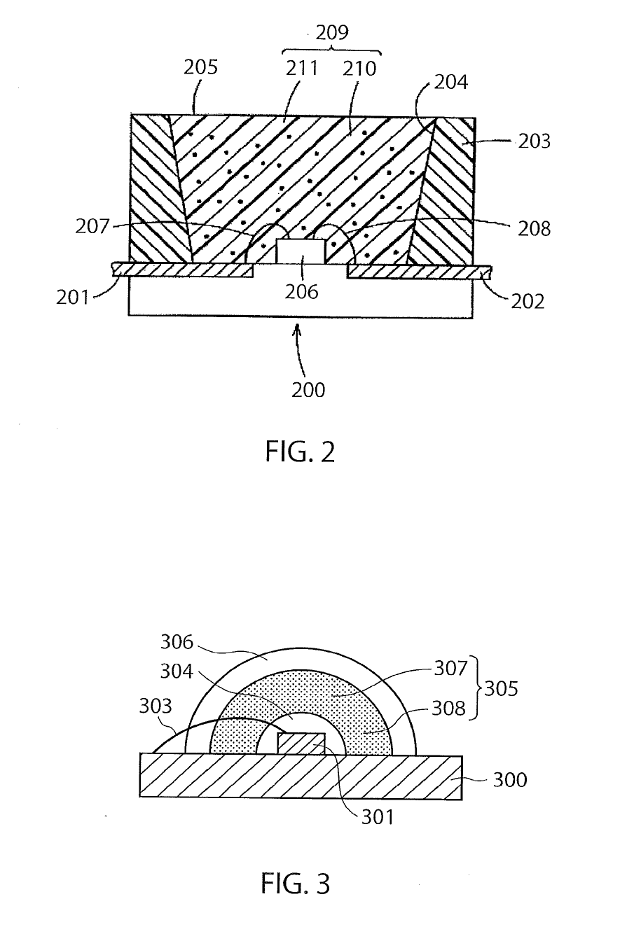

A light-emitting device according to an embodiment comprises: a fluorescence light-emitting layer containing the above-described phosphor; and a light-emitting element for exciting the above-described phosphor. FIG. 2 is a schematic view illustrating the configuration of the light-emitting device according to the embodiment.

In the light-emitting device illustrated in FIG. 2, leads 201 and 202, and a package cup 203 are placed on a substrate 200. The substrate 200 and the package cup 203 are resinous. The package cup 203 has a recess 205 of which the top is larger than the bottom. The side of the recess functions as a reflecting surface 204.

A light-emitting element 206 is mounted, with an Ag paste or the like, on the center of the generally circular bottom surface of the recess 205. The light-emitting element 206 used emits light having a luminescence peak in a wavelength range of 400 to 500 nm. Examples of the light-emitting element 206 include a light-emitting diode, a laser diode, and the like. Specific examples of the light-emitting element 206 include, but are not limited to, semiconductor light-emitting elements such as GaN-based semiconductor light-emitting elements; and the like.

The p-electrode and n-electrode (not illustrated) of the light-emitting element 206 are connected, through bonding wires 207 and 208 comprising Au or the like, to the lead 201 and the lead 202, respectively. The arrangement of the leads 201 and 202 can be appropriately changed.

As the light-emitting element 206, a flip-chip-type light-emitting element including an n-type electrode and a p-type electrode on the same surface can also be used. In such a case, problems caused by a wire, such as the disconnection and peeling of the wire, and the absorption of light into the wire, are solved to provide a semiconductor light-emitting device with high reliability and high luminance. The following structure can also be made using a light-emitting element comprising an n-type substrate. An n-electrode is formed on the back surface of the n-type substrate of the light-emitting element, and a p-electrode is formed on the top surface of a p-type semiconductor layer layered on the substrate. The n-electrode is mounted on a lead, and the p-electrode is connected to the other lead through a wire.

A fluorescence light-emitting layer 209 containing a phosphor 210 according to an embodiment is placed in the recess 205 of the package cup 203. In the fluorescence light-emitting layer 209, the phosphor 210 in an amount of 5 to 60 mass % is contained, for example, in a resin layer 211 comprising silicone resin. As described above, the phosphor according to the present embodiment contains Sr₂Al₃Si₇ON₁₃ as a base material, and such an oxynitride has high covalency. Therefore, the phosphor according to the present embodiment is hydrophobic and has excellent compatibility with resins. Accordingly, scattering on the interface between the resin layer and the phosphor is markedly suppressed to improve light extraction efficiency.

The yellow light-emitting phosphor according to the present embodiment has favorable temperature characteristics and can emit yellow light excellent in color rendering properties with high efficiency. A white light-emitting device having excellent luminescence properties is provided by combining the yellow light-emitting phosphor with a light-emitting element that emits light having a luminescence peak in a wavelength range of 400 to 500 nm.

The size and kind of the light-emitting element 206 as well as the dimension and shape of the recess 205 can be appropriately changed.

The light-emitting device according to the embodiment is not limited to such package-cup-type light-emitting devices as illustrated in FIG. 2 but can be appropriately changed. Specifically, the phosphor of the embodiment can also be applied to a bullet-type LED or a surface-mount-type LED, to obtain a similar effect.

FIG. 3 illustrates a schematic view illustrating the configuration of a light-emitting device according to another embodiment. In the light-emitting device illustrated in the figure, a p-electrode and an n-electrode (not illustrated) are formed in a predetermined region in an insulating substrate 301 with heat radiation characteristics, and a light-emitting element 302 is placed thereon. The material of the insulating substrate with heat radiation characteristics may be, for example, AlN.

One electrode in the light-emitting element 302 is disposed on the bottom surface of the light-emitting element 302 and is electrically connected to the n-electrode of the insulating substrate 301 with heat radiation characteristics. The other electrode in the light-emitting element 302 is connected, through a gold wire 303, to the p-electrode (not illustrated) on the insulating substrate 301 with heat radiation characteristics. As the light-emitting element 302, a light-emitting diode that emits light having a luminescence peak in a wavelength range of 400 to 500 nm is used.

An internal transparent resin layer 304 having a dome shape, a fluorescence light-emitting layer 305, and an external transparent resin layer 306 are sequentially formed on the light-emitting element 302. The internal transparent resin layer 304 and the external transparent resin layer 306 can be form with, for example, silicone or the like. In the fluorescence light-emitting layer 305, for example, a yellow light-emitting phosphor 307 of the present embodiment is contained in a resin layer 308 comprising silicone resin.

In the light-emitting device illustrated in FIG. 3, the fluorescence light-emitting layer 305 comprising the yellow light-emitting phosphor according to the present embodiment can be easily produced by adopting a technique such as vacuum printing or drop-coating from a dispenser. Moreover, since such a fluorescence light-emitting layer 305 is positioned by the internal transparent resin layer 304 and the external transparent resin layer 306, an effect of improving the extraction efficiency is obtained.

The fluorescence light-emitting layer of the light-emitting device according to the present embodiment may contain a green light-emitting phosphor that emits green light by excitation with blue light and a red light-emitting phosphor that emits red light by excitation with blue light as well as the yellow light-emitting phosphor of the present embodiment. In such a case, a white light-emitting device superior in color rendering properties is provided.

Yellow light is also emitted when the yellow light-emitting phosphor according to the present embodiment is excited with light in an ultraviolet region of 250 to 400 nm. Accordingly, a white light-emitting device can also be formed by combining the phosphor according to the present embodiment with, for example, a blue light-emitting phosphor that emits blue light by excitation with ultraviolet light and a light-emitting element such as an ultraviolet light-emitting diode. A fluorescence light-emitting layer in such a white light-emitting device may contain a phosphor that emits light having a peak in another wavelength range by excitation with ultraviolet light, as well as the yellow light-emitting phosphor of the present embodiment. Examples of the phosphor include a phosphor that emits red light by excitation with ultraviolet light, a phosphor that emits green light by excitation with ultraviolet light, and the like.

As described above, the phosphor of the present embodiment has favorable temperature characteristics and can emit yellow light excellent in color rendering properties with high efficiency. A white light-emitting device having excellent luminescence properties can be provided using a few kinds of phosphors by combining such a yellow light-emitting phosphor of the present embodiment with a light-emitting element that emits light having a luminescence peak in a wavelength range of 250 to 500 nm.

### EXAMPLES

Specific examples of the phosphor and light-emitting device according to the embodiments of the present invention are described as follows.

### Comparative Example

SrSi₂, CeCl₃, and Si₃N₄ were prepared to first synthesize an intermediate product. The masses of blended SrSi₂, CeCl₃, and Si₃N₄ were 8.369 g, 0.370 g, and 1.328 g, respectively. The blended raw material powders were dry-mixed using a planetary ball mill in a glove box under nitrogen atmosphere.

The resulting mixture was encased in a boron nitride (BN) crucible, and was fired in hydrogen/nitrogen atmosphere at a pressure of one atmosphere at 1500° C. for 4 hours. The fired product was taken out of the crucible and was crushed in an agate mortar. The fired product that had been crushed was re-encased in the crucible, and was fired at 1500° C. for 4 hours in the same manner, to obtain the intermediate product.

The weighing of each of 5.000 g of the intermediate product obtained in such a manner, 1.556 g of Si₃N₄, and 1.105 g of AlN was performed, and they were dry-blended using the planetary ball mill.

The resulting mixture was encased in the boron nitride (BN) crucible, and was fired in nitrogen atmosphere at a pressure of 7.5 atmospheres at 1850° C. for 10 hours. The fired product was taken out of the crucible and was crushed in the agate mortar. A phosphor of Comparative Example 1 was obtained by repeating the firing/crushing four times in total.

The obtained phosphor, which was a powder with a yellow body color, was confirmed to emit yellow light when excited with black light.

### Example 1

A phosphor produced in the same manner as in Comparative Example and Si₃N₄ balls of 3 mm in diameter were encased in a Si₃N₄ pot, and were ground using a planetary ball mill in three sets of 300 rpm and 3 minutes while changing a rotation direction. The median diameter (D50) of the particle diameters of the ground phosphor was 9.7 μm. The resulting ground mixture was encased in a boron nitride (BN) crucible, was fired in nitrogen atmosphere at a pressure of 7.5 atmospheres at 1850° C. for 10 hours, and was appropriately crushed in an agate mortar, to obtain a phosphor of Example 1.

The obtained phosphor, which was a powder with a yellow body color, was confirmed to emit yellow light when excited with black light.

### Example 2

SrSi₂, CeCl₃, and Si₃N₄ were prepared to first synthesize an intermediate product. The masses of blended SrSi₂, CeCl₃, and Si₃N₄ were 8.369 g, 0.370 g, and 1.328 g, respectively. The blended raw material powders were dry-mixed using a planetary ball mill in a glove box under nitrogen atmosphere.

The resulting mixture was encased in a boron nitride (BN) crucible, and was fired in hydrogen/nitrogen atmosphere at a pressure of one atmosphere at 1500° C. for 4 hours. The fired product was taken out of the crucible and was crushed in an agate mortar. Then, the crushed product and Si₃N₄ balls of 3 mm in diameter were encased in a Si₃N₄ pot, and were ground using a planetary ball mill in three sets of 300 rpm and 3 minutes while changing a rotation direction. The resulting crushed mixture was encased in the boron nitride (BN) crucible, and was fired at 1500° C. for 4 hours in the same manner, to obtain the intermediate product.

The weighing of each of 5.000 g of the intermediate product obtained in such a manner, 1.556 g of Si₃N₄, and 1.105 g of AlN was performed, and they were dry-blended using the planetary ball mill.

The resulting mixture was encased in the boron nitride (BN) crucible, and was fired in nitrogen atmosphere at a pressure of 7.5 atmospheres at 1850° C. for 10 hours. The fired product was taken out of the crucible and was crushed in the agate mortar. The firing/crushing was repeated four times in total. The fired product and Si₃N₄ balls of 3 mm in diameter were encased in a Si₃N₄ pot, and were ground using the planetary ball mill in three sets of 300 rpm and 3 minutes while changing a rotation direction. The resulting ground mixture was further encased in the boron nitride (BN) crucible, was fired in nitrogen atmosphere at a pressure of 7.5 atmospheres at 1850° C. for 10 hours, and was appropriately crushed in the agate mortar, to obtain a phosphor of Example 2.

The obtained phosphor, which was a powder with a yellow body color, was confirmed to emit yellow light when excited with black light.

### Example 3

SrSi₂, CeCl₃, AlN, and Si₃N₄ were prepared to first synthesize an intermediate product. The masses of blended SrSi₂, CeCl₃, AlN, and Si₃N₄ were 8.369 g, 0.370 g, 0.512 g, and 0.743 g, respectively. The blended raw material powders were dry-mixed using a planetary ball mill in a glove box under nitrogen atmosphere.

The resulting mixture was encased in a boron nitride (BN) crucible, and was fired in hydrogen/nitrogen atmosphere at a pressure of one atmosphere at 1500° C. for 12 hours. The fired product was taken out of the crucible and was crushed in an agate mortar. The fired product that had been crushed was re-encased in the crucible, and was fired at 1500° C. for 12 hours in the same manner, to obtain the intermediate product.

The weighing of each of 7.500 g of the intermediate product, 2.734 g of Si₃N₄, and 1.297 g of AlN was performed, and they were dry-blended using the planetary ball mill.

The resulting mixture was encased in the boron nitride (BN) crucible, and was fired in nitrogen atmosphere at a pressure of 7.5 atmospheres at 1850° C. for 10 hours. The fired product was taken out of the crucible and was crushed in the agate mortar. The firing/crushing was repeated four times in total. The fired product and Si₃N₄ balls of 3 mm in diameter were encased in a Si₃N₄ pot, and were ground using the planetary ball mill in three sets of 300 rpm and 3 minutes while changing a rotation direction. The resulting ground mixture was encased in the boron nitride (BN) crucible, and was fired in nitrogen atmosphere at a pressure of 7.5 atmospheres at 1850° C. for 10 hours. The fired product was taken out of the crucible, and was crushed in the agate mortar. The fired product that had been crushed was re-encased in the crucible, was fired at 1850° C. for 10 hours, and was then gently crushed in the agate mortar, to obtain a phosphor of Example 3.

The obtained phosphor, which was a powder with a yellow body color, was confirmed to emit yellow light when excited with black light.

### Example 4

SrSi₂, CeCl₃, AlN, and Si₃N₄ were prepared to first synthesize an intermediate product. The masses of blended SrSi₂, CeCl₃, AlN, and Si₃N₄ were 8.369 g, 0.370 g, 0.512 g, and 0.743 g, respectively. The blended raw material powders were dry-mixed using a planetary ball mill in a glove box under nitrogen atmosphere.

The resulting mixture was encased in a boron nitride (BN) crucible, and was fired in hydrogen/nitrogen atmosphere at a pressure of one atmosphere at 1500° C. for 12 hours. The fired product was taken out of the crucible and was crushed in an agate mortar. The fired product that had been crushed was re-encased in the crucible, and was fired at 1500° C. for 12 hours in the same manner, to obtain the intermediate product.

The weighing of each of 7.500 g of the intermediate product, 2.734 g of Si₃N₄, and 1.297 g of AlN was performed, and they were dry-blended using the planetary ball mill.

The resulting mixture was encased in the boron nitride (BN) crucible, was subjected to tapping 100 times to enhance the packing density of the mixture, and was then fired in nitrogen atmosphere at a pressure of 7.5 atmospheres at 1850° C. for 10 hours. The fired product was taken out of the crucible and was crushed in the agate mortar. The firing/crushing was repeated four times in total. The powder and Si₃N₄ balls of 3 mm in diameter were encased in a Si₃N₄ pot, and were ground using the planetary ball mill in three sets of 300 rpm and 3 minutes while changing a rotation direction. The resulting ground mixture was encased in the boron nitride (BN) crucible, was subjected to tapping 100 times to enhance the packing density of the mixture, and was then fired in nitrogen atmosphere at a pressure of 7.5 atmospheres at 1850° C. for 10 hours. The fired product was taken out of the crucible, and was crushed in the agate mortar. The fired product that had been crushed was re-encased in the crucible, was subjected to tapping 100 times to enhance the packing density of the product, was then fired at 1850° C. for 10 hours, and was then gently crushed in the agate mortar, to obtain a phosphor of Example 4.

The obtained phosphor, which was a powder with a yellow body color, was confirmed to emit yellow light when excited with black light.

### Evaluation of Luminescence Properties

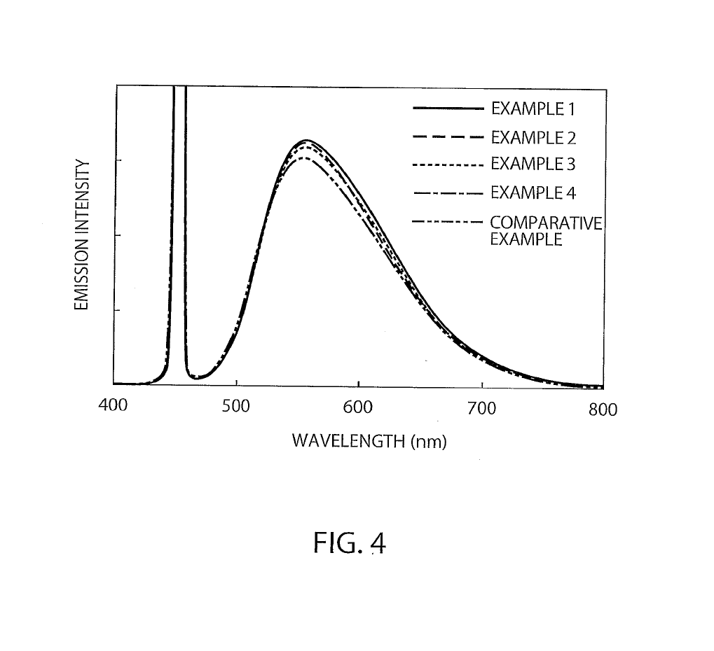

FIG. 4 shows the emission spectra of the phosphors excited with light having an emission wavelength of 450 nm dispersed from a xenon lamp. In FIG. 4, emitted light having a narrow half-width at around 450 nm is not light emitted from the phosphors but reflected excitation light. High emission intensities with peak wavelengths of 553 to 556 nm were confirmed. It was observed that each of the phosphors of Examples 1 to 4 showed the emission intensity that was higher than that of the phosphor of Comparative Example 1. The half-widths of the emission spectra determined by using an instantaneous multichannel spectrometer were 118 to 119 nm. A half-width is one of the indices of the color rendering properties of white light emitted from a light-emitting device. Commonly, a wider half-width easily results in white light having higher color rendering properties. It was shown that white light having excellent color rendering properties was easily provided by using the phosphor of Example 1 because of its wide half-width. The peak wavelengths, absorptances, internal quantum efficiencies, and external quantum efficiencies of emitted light in the case of the excitation at 450 nm, provided from the emission spectra shown in FIG. 4, are listed in Table 1.

TABLE 1

| | Peak | | Internal | External |
|---|---|---|---|---|
| | wavelength | | quantum | quantum |
| | (nm) | Absorptance | efficiency | efficiency |
| Example 1 | 554 | 0.79 | 0.90 | 0.71 |
| Example 2 | 553 | 0.78 | 0.90 | 0.71 |
| Example 3 | 555 | 0.82 | 0.89 | 0.72 |
| Example 4 | 556 | 0.81 | 0.89 | 0.73 |
| Comparative | 551 | 0.79 | 0.85 | 0.67 |
| Example | | | | |

### Powder X-Ray Diffraction

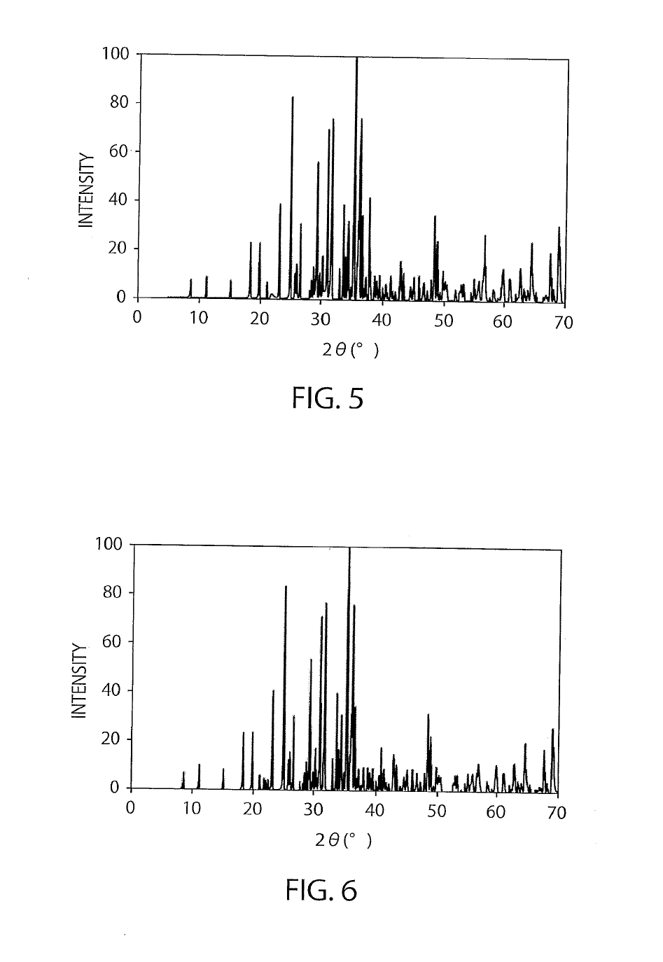

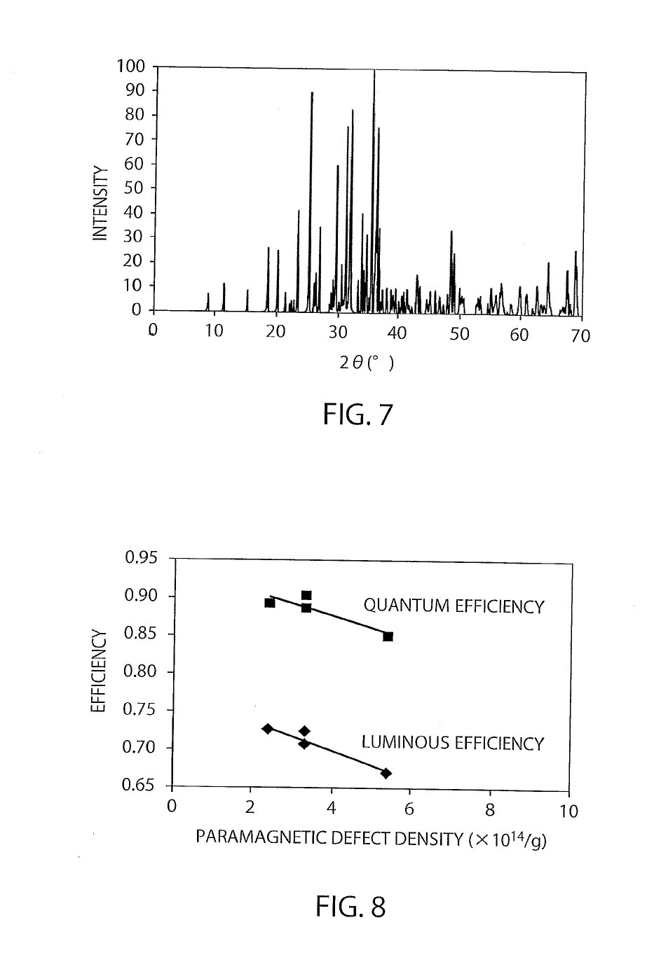

A diffracting device with a monochromator (Smart Lab (trade name), manufactured by Rigaku Corporation) using a Cu—Kα line as a radiation source was used for measuring an X-ray diffraction spectrum. Before the measurement, an automatic setting attached to the device was performed for correcting the positions of an X-ray source and a diffraction system and for correcting the slight displacement of a goniometer, followed by measuring the X-ray diffraction profile of standard silicon (Si), to confirm the achievement of the corrections. The powder X-ray diffraction patterns of Examples 1 to 2 and Comparative Example are shown in FIGS. 5 to 7, respectively. The patterns of FIGS. 5 to 7 are patterns obtained by removing backgrounds with analysis software “PDXL2” (trade name, manufactured by Rigaku Corporation).

### Measurement of Paramagnetic Defect Density

The paramagnetic defect densities of the phosphors of Examples 2, 3, and 4 and Comparative Example were measured by the following method:

Electron paramagnetic resonance measuring apparatus Elexsys E580 (trade name, manufactured by Bruker Corporation),

Central magnetic field: around 3368 G,

Magnetic field sweep width: 150 G,

Modulation: 100 kHz, 5 G, and

Microwave: 9.43 GHz, 0.026 mW.

The paramagnetic defect density of each phosphor obtained by the measurement is listed in Table 2.

TABLE 2

| | Paramagnetic |
|---|---|
| | defect density |
| | (per gram) |
| Example 2 | 3.3 × 10¹⁴ |
| Example 3 | 3.3 × 10¹⁴ |
| Example 4 | 2.4 × 10¹⁴ |
| Comparative | 5.4 × 10¹⁴ |
| Example | |

The relationships of the quantum efficiencies and paramagnetic defect densities of the phosphors of Examples 2 to 4 and Comparative Example are shown in FIG. 8. FIG. 8 reveals that a paramagnetic defect density of 5×10¹⁴ or less is particularly preferred.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the invention.

1. A phosphor, exhibiting a luminescence peak in a wavelength range of 500 to 600 nm when excited with light having a luminescence peak within a wavelength range of 250 to 500 nm,
wherein said phosphor is represented by the following formula (1):
((SrₚM₁₋ₚ)₁₋ₓCeₓ)_{2y}Al_{z}Si_{10-z}OᵤN_{w} (1)
wherein M is at least one of alkaline earth metals; and
0≦p≦1,
0<x≦1,
0.8≦y≦1.1,
2≦z≦3.5,
0<u≦1,
1.8≦z−u, and
13≦u+w≦15
are satisfied; and
said phosphor having paramagnetic defects and a paramagnetic defect density of said phosphor being 5×10¹⁴ per gram or less.

2. The phosphor according to claim 1, wherein M is at least one selected from Ba, Ca, and Mg.

3. The phosphor according to claim 1, comprising a crystal structure that is substantially identical to a crystal structure of Sr₂Al₃Si₇ON₁₃.

4. A light-emitting device, comprising:
a light-emitting element that emits light having a luminescence peak in a wavelength range of 250 to 500 nm; and
a fluorescence light-emitting layer comprising a yellow light-emitting phosphor that receives light from the light-emitting element and emits yellow light, said yellow light-emitting phosphor being the phosphor according to claim 1.

5. The light-emitting device according to claim 4, wherein the fluorescence light-emitting layer further comprises a phosphor that emits green light and a phosphor that emits red light.

6. A light-emitting device, comprising:
a light-emitting element that emits light having a luminescence peak in a wavelength range of 250 to 400 nm; and
a fluorescence light-emitting layer containing a yellow light-emitting phosphor that receives light from the light-emitting element and emits yellow light and a blue light-emitting phosphor that receives light from the light-emitting element and emits blue light, said yellow light-emitting phosphor being the phosphor according to claim 1.

7. A method for producing the phosphor according to claim 1, comprising:
a raw material mixing step of mixing a Sr-containing raw material selected from nitrides, silicides, carbides, carbonates, hydroxides, and oxides of Sr, a M-containing raw material selected from nitrides, carbides, carbonates, hydroxides, and oxides of M, an Al-containing raw material selected from nitrides, oxides, and carbides of Al, a Si-containing raw material selected from nitrides, oxides, and carbides of Si, and a Ce-containing raw material selected from chlorides, oxides, nitrides, and carbonates of Ce, to obtain a mixture;
a firing step of firing the mixture; and
a crushing step of crushing a fired product obtained after the firing,
wherein a combination of the firing step and the crushing step is repeated twice or more.

8. The method according to claim 7, wherein said mixture is fired at 1500 to 2000° C. under a pressure of 5 atmospheres or more.

9. The method according to claim 7, wherein said mixture is fired in nitrogen atmosphere.

10. The method according to claim 7, wherein said fired product is crushed in a mortar, a planetary mill, or a ball mill.

11. The method according to claim 7, wherein the last crushing step in said crushing steps is performed in a ball mill.

12. The method according to claim 7, further comprising:
a step of cleaning the fired product after the firing.
